(19) United States
(12) Patent Application Publication
(10) Pub. No.: US 2007/0210945 A1
(43) Pub. Date: Sep. 13, 2007

(54) PERSONAL MULTIPLE-IDENTIFICATION DEVICE

(75) Inventors: Francis Chu, Singapore (SG); Brian Regienczuk, Atlanta, GA (US); Ed Stamm, Roswell, GA (US); Anders Smith, San Francisco, CA (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/599,407

(22) PCT Filed: Mar. 25, 2005
(86) PCT No.: PCT/IB05/51039

§ 371 Date: Sep. 28, 2006

Related U.S. Application Data
(60) Provisional application No. 60/557,500, filed on Mar. 30, 2004.
(60) Provisional application No. 60/636,456, filed on Dec. 16, 2004.

(51) Int. Cl. H03M 7/30

(52) U.S. Cl. 341/87

(57) ABSTRACT

A major drawback to the proliferation of RFIDs in, for example, a retail environment, is that patrons are wary of how much information about them will be transmitted to a proprietor, and how that information will be used. Such privacy concerns are seen as one of the biggest hindrances to the ubiquity of RFIDs in many environments. Additionally, patrons will have an overwhelming amount of information transmitted to their devices containing RFIDs. To address these privacy concerns, the invention includes a device, a system, and a method for transmitting a personal profile includes: a memory containing a personal profile; a personal profile selection component; and a transmitter for transmitting a signal, the signal including at least one subset of the personal profile selected using the personal profile selection component.

Radio-frequency identifier (RFID) tags deliver information by radio signals to a reader just as a transponder does. This permits machines to read data associated with an object. One of the attractions of RFID devices is their potential to carry a large quantity of information. This is in contrast to conventional bar codes whose data capacity is much more limited. Still other devices for storing information include printed and non-printed (e.g., etched) machine-readable symbols (e.g., using a pattern recognition process) and digital watermarks.

RFID tags may be programmable and may also include sensors that can record various environmental factors into a tag.

If a RFID is attached to a product, it can uniquely identify that particular product, which could be tied in a central database to its date of manufacture, the shipment vessel it was conveyed in, its date of shipment, the retailer to whom it was shipped, to whom it was sold, how it was manufactured, when it was manufactured, etc. Another advantage is that some are capable of being scanned by holding a reader some distance away and without precisely aiming the reader with respect to the MRL device. Some readers are capable or reading many RFIDs at once. Additionally, RFIDs can be used to identify persons, such as those in a specific environment, such as a store, restaurant, etc. Proprietors of such environments can track many types of information about patrons who either carry RFIDs or other kinds of near-field devices or who receive information from RFIDs in the proprietor's environment. For example, a proprietor can track what a patron purchased, personal information about the patron, such as physical characteristics, preferred methods of payment, and any other information a patron's RFID or MRL device will transmit when it receives a request from a proprietor's reader.

Currently, RFIDs are being embedded in mobile phones, PDAs and other portable electronic devices a patron may carry with them. Additionally, RFIDs can be mounted on patron's clothing, or even subdermally implanted in a patron's body.

A major drawback to the proliferation of RFIDs in, for example, a retail environment, is that patrons are wary of how much information about them will be transmitted to a proprietor, and how that information will be used. Such privacy concerns are seen as one of the biggest hindrances to the ubiquity of RFIDs in many environments. Additionally, patrons will have an overwhelming amount of information transmitted to their devices containing RFIDs.

To address these privacy concerns, the invention includes in one aspect, a device for transmitting a personal profile includes: a memory containing a personal profile; a personal profile selection component; and a transmitter for transmitting a signal, the signal including at least one subset of the personal profile selected using the personal profile selection component.

In one embodiment, the personal profile includes more than one subset.

In another embodiment, the personal profile selection component includes a switch. In another embodiment, the switch is manually operable by a patron.

In one embodiment, the transmitter is an RFID.

In one embodiment, the device further includes a transceiver which receives a request to transmit the at least one subset of the personal profile from a reader. In another embodiment, the reader exclusively receives the signal.

In one embodiment, the personal profile may be altered and stored in the memory. In another embodiment, the memory is altered wirelessly, through a wired connection, or both.

In one embodiment, the at least one personal profile includes information regarding user status, transmitter mode, reader access, and/or payment.

In one embodiment, the device includes a key chain, a credit card, a smart card, a mobile phone, a PDA, a wireless device, a portable microcomputer, or a wearable device.

In another aspect, a device for limiting the transmission and/or receiving of a personal profile includes: a personal profile selection component for selecting at least one subset of the personal profile; and a transceiver that transmits a signal upon receiving a demand from a reader, said signal comprising at least one subset of the personal profile selected using the personal profile selection component.

In one embodiment, a user defines at least one setting and at least one option, the option and setting forming the at least one subset.

In one embodiment, the memory is programmable and the user can program at least one parameter of the at least one subset.

In one embodiment, the transceiver accesses a memory that is external to the device and can be accessed wirelessly by the device.

In one embodiment, the transceiver further comprises an RFID tag. In another embodiment, the transceiver receives a signal containing information and only stores the information in the memory if the information matches an option contained in the subset of the personal profile.

In another aspect, a device for selecting and transmitting a personal profile includes: a memory containing a personal profile having at least a first and a second subset; at least two personal profile selection components for selecting the first and/or the second subset of the personal profile; and a transmitter for transmitting the first and/or the second subset.

In one embodiment, the device includes an arbiter for selecting an overlap between the first and the second subsets. In another embodiment, the arbiter is software, hardware, or both software and hardware. In another embodiment, the transmitter transmits a signal including the selected overlap.

In another aspect, a system for allowing a personal profile to be read includes: a device comprising: a memory containing a personal profile; a personal profile selection component; and a tag for transmitting a signal; a reader configured to transmit a request, wherein said tag transmits said signal, and the signal includes exclusively at least one subset of the personal profile selected using the personal profile selection component.

In another aspect, a method of selecting a personal profile in an environment includes the steps of: entering a personal profile in a memory; generating at least one subset of the personal profile; selecting the at least one subset; transmitting and/or receiving information based on the at least one subset upon receiving a request in the environment.

In one embodiment, the generating step includes generating at least two subsets. In another embodiment, the generating step includes automatically generating the at least one subset from the personal profile. In another embodiment, the method includes receiving a request to transmit from a triggering the selection step by recognizing a request to transmit from an environment.

In another embodiment, the recognizing step includes identifying the source of the triggering step and transmitting the subset based the environment's identification. In another embodiment, the method includes receiving a request to transmit from a reader in an environment.

The invention provides many advantages, some of which are elucidated with reference to the embodiments below.

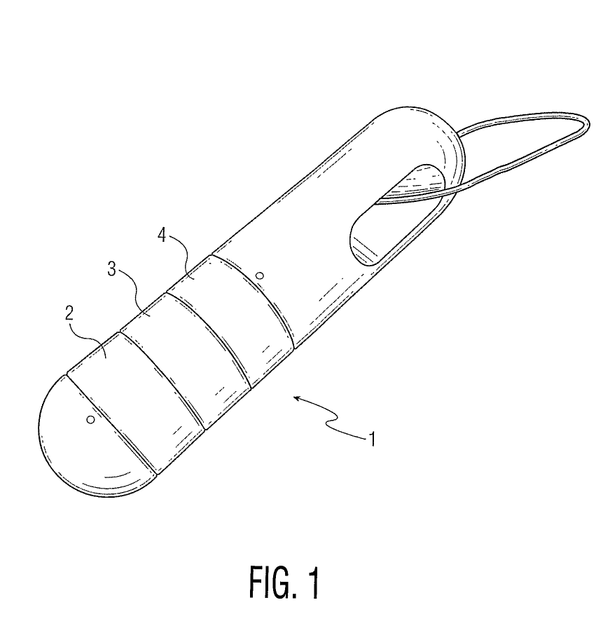

FIG. 1 depicts a device with a personal profile selector in a first configuration;

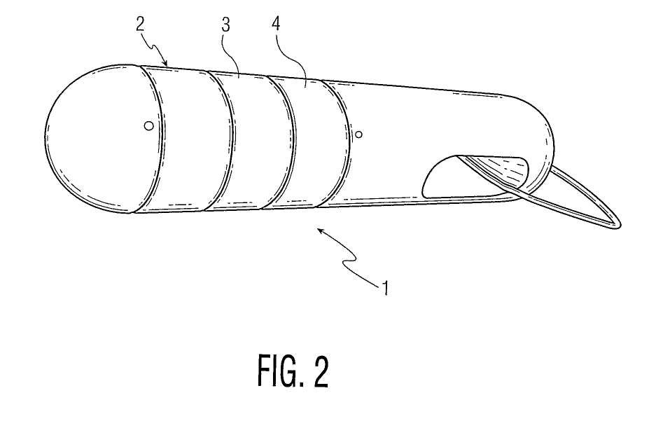

FIG. 2 depicts the device of FIG. 1 in a second configuration;

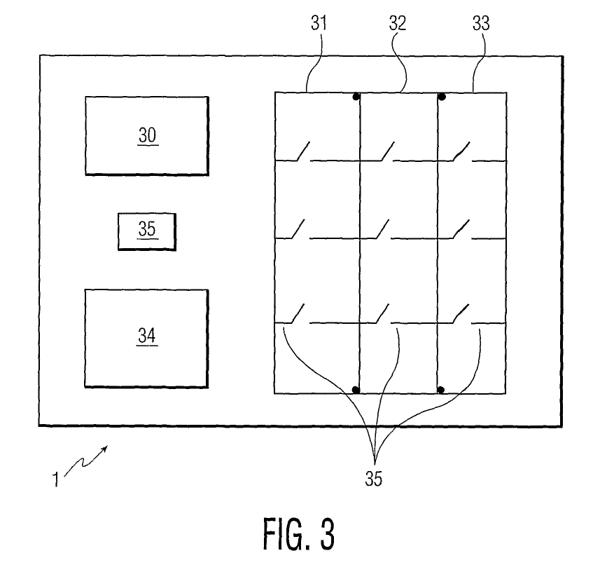

FIG. 3 depicts a device with a personal profile selector, a memory, and a tag;

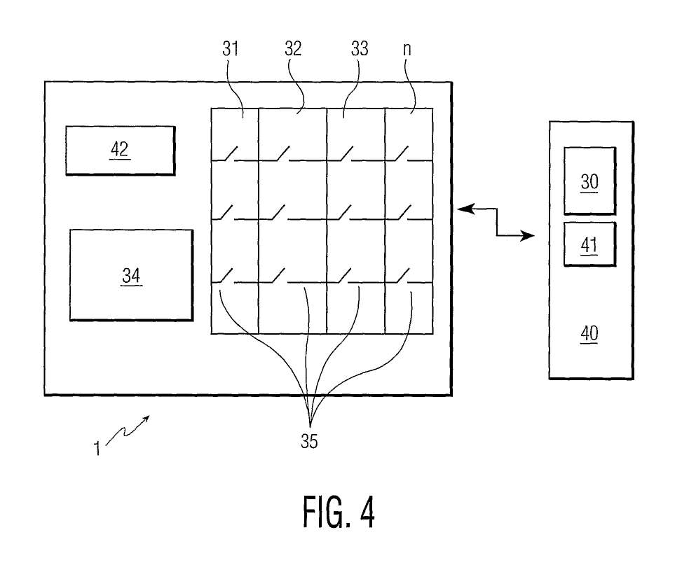

FIG. 4 depicts the device of FIG. 4 where the memory is separate from the device;

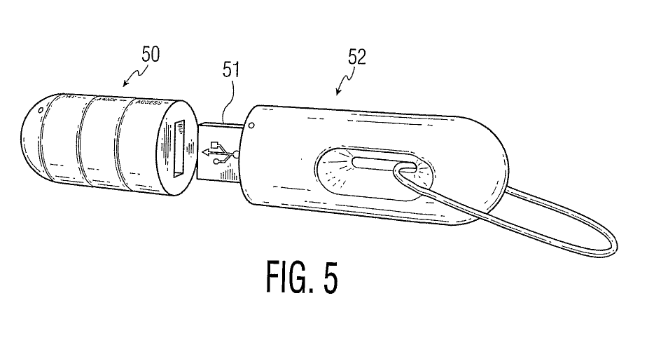

FIG. 5 depicts the device of FIG. 1 containing an input;

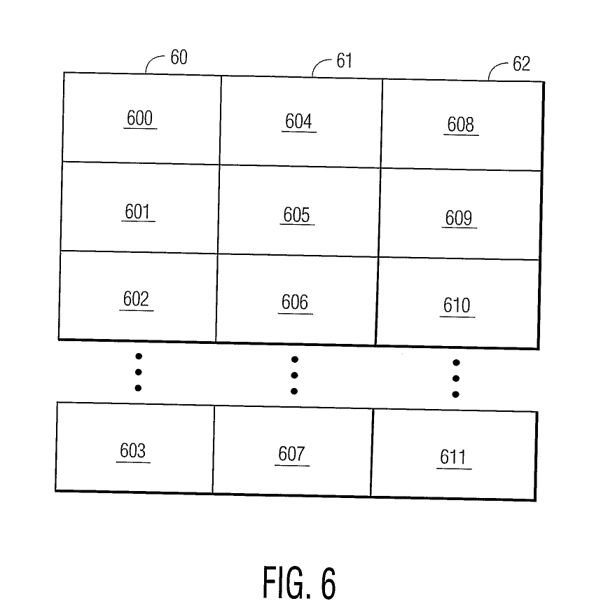

FIG. 6 depicts settings and options forming a personal profile;

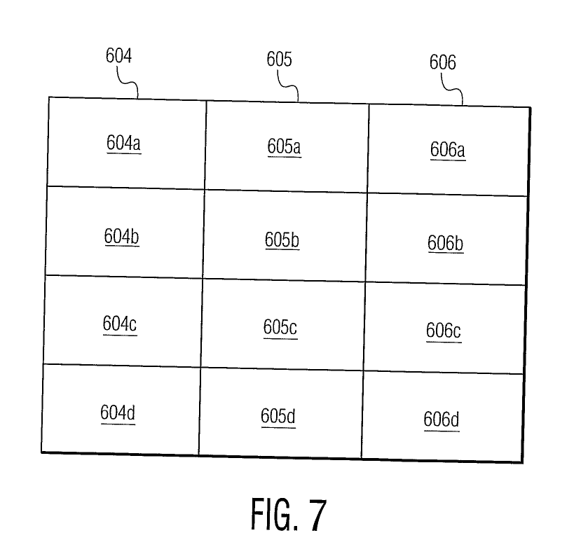

FIG. 7 depicts mode options of a personal profile;

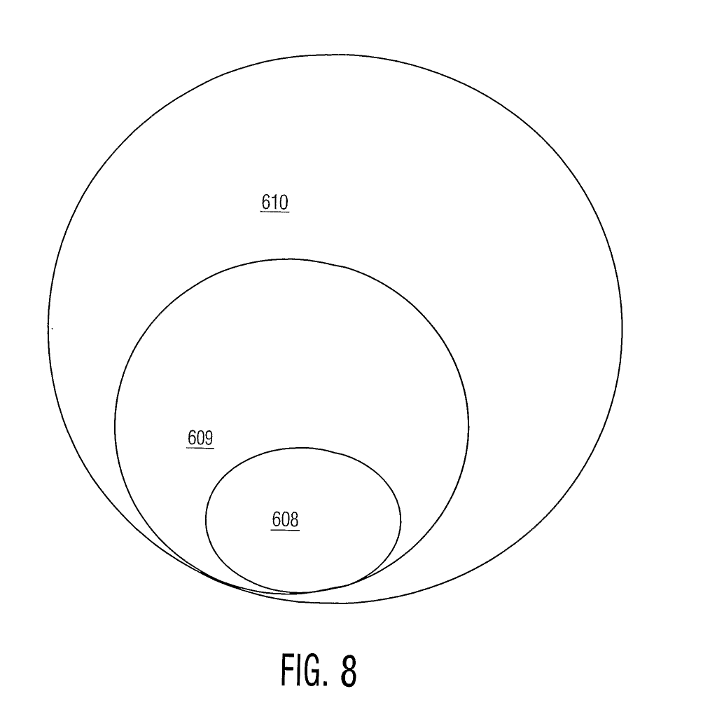

FIG. 8 depicts access options of a personal profile;

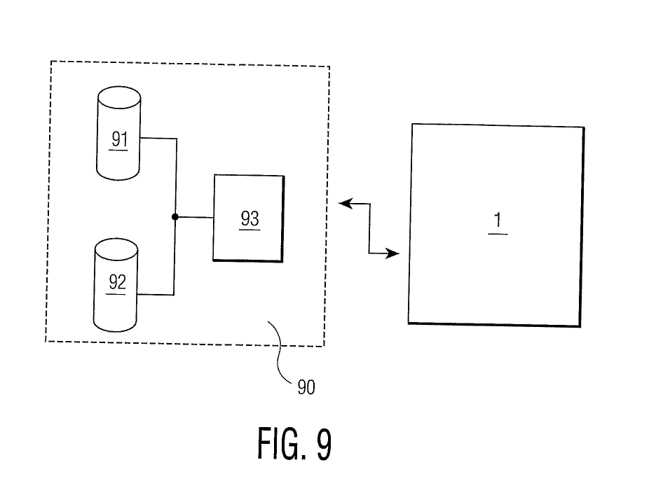

FIG. 9 depicts a system for allowing a personal profile to be read; and

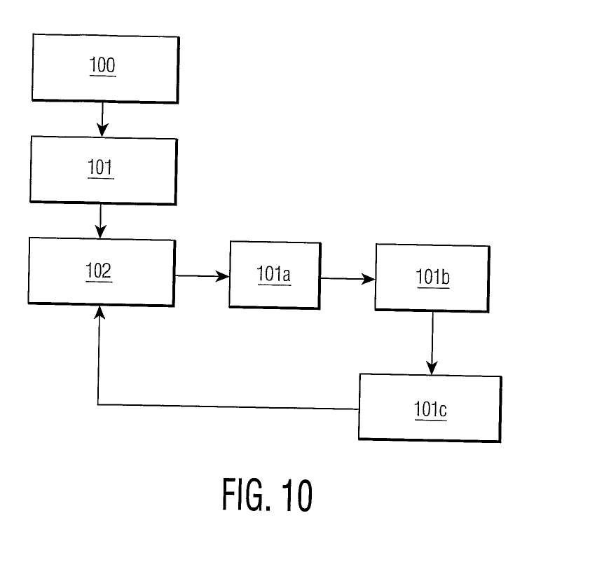

FIG. 10 depicts a flow chart of a method of selecting a personal profile in an environment.

FIG. 1 depicts a device 1 that transmits a personal profile. Information entered by a patron and stored in a memory forms the personal profile. A subset of a personal file is a limited portion of the information contained in the personal profile. Subsets may limit what information can be transmitted from or received by device 1. Subsets may be formed by settings corresponding to different categories of information. Each setting may include options that limit the particular information in the subset that can be either transmitted or received.

Device 1 can be a keychain (as depicted in FIG. 1), a credit card, a smart card, a mobile phone, a PDA, a wireless device, a portable microcomputer, a garment, or any other portable device which can contain an RFID tag. If, for example, a patron carries device 1 into a retail environment, they can select what information they wish to receive and what information they wish to transmit. This is achieved, for example, by activating personal profile selection components 2, 3, 4.

In the example of FIG. 1, personal profile selection component 2 contains the options “visa”, “amex”, and “debit”. These options correspond to three different methods of payment. If, for example, a patron enters a retail environment and selects “visa”, upon selecting a product to purchase, payment will be charged to the patron's visa account. The visa account number can be programmed into a memory within device 1, recalled upon request from a reader in the environment (at checkout), and transmitted by a tag within device 1. If, for example, a patron enters a retail environment and selects the option “amex”, upon selecting a product to purchase, payment will be charged to the patron's amex account. The amex account number (e.g., information) can be programmed into a memory within device 1, recalled upon request from a reader in the environment (at checkout), and transmitted by a tag within device 1. A patron may program any information a proprietor might read into the memory of device 1 (i.e., account numbers, types of credit cards, etc.).

Personal profile selection component 3 selects a mode of shopping a patron may desire. Selecting the mode setting may limit the type of information a patron may receive from the environment. For example, “new” mode may only receive information from transmitters in the environment that relates to new products entering the environment within a given amount of time (i.e., within the last six months). “Offers” mode may only read from the environment for various offers available to patrons (i.e., ongoing sales, or customer loyalty discounts). “Deal” may only read information relating to, for example, products with a certain percent discount of the full price (i.e., 20% or greater sale).

Personal profile selection component 4 selects an access setting that a patron will allow the environment to read from device 1. For example, the “none” option can be configured to not allow a proprietor of an environment to read any information from patron's device 1. The “limited” option may allow a proprietor to read some portion of a patron's information from device 1. The “full” option may allow unlimited access to a patron's information contained in a memory. A patron may program the information corresponding to each option (e.g., what particular information may be read in a particular setting).

In the example of FIG. 1, a patron selected the “visa” option from the payment setting in personal profile selection component 2, the “new” option from the mode setting of personal profile selection component 3, and the “none” option from the access setting of personal profile selection component 4. Thus, in the example of FIG. 1, the total personal profile subset selected on device 1 will be “visa”, “new”, “none”.

In the example of FIG. 1, device 1 allows for the selection of nine possible personal profile subsets by rotating personal profile selection components 2, 3, 4 to various positions (e.g., three personal profile selectors times thee options each). Device 1 can contain any number of personal profile selection components, and each personal profile selection component can contain any number of options. Personal profile selection components 2, 3, and 4 can be any type of selection component known in the art, including, for example, dials, switches, buttons, etc.

FIG. 2 depicts device 1 in the configuration “visa”, “offers”, “none” by rotating mode personal profile selection component 3 to the “mode” option.

FIG. 3 depicts an example of a device 1 containing a memory 30, personal profile selection components 31, 32, and 33, a tag 34, and an arbitrator 35. A patron will store information in memory 30 corresponding to available options in personal profile selectors 31, 32, 33. Each switch 35 in personal profile selection components 31, 32, 33 corresponds to a different option. When a patron closes a switch 35, memory 30 will allow tag 34 to transmit or receive information pertaining to the option to which switch 35 corresponds. Switches 35 may be analog switches, solid state switches, software switches, or any other switch known to one of skill in the art. Additionally, switches 35 can be a software matrix whereby selection of various options will select points on the matrix to form personal profile subsets. Memory 30 may be a solid-state memory, a RAM, a ROM, a software memory, or any other memory known to one of skill in the art. A patron may select any switch 35 or no switches at all (i.e., in the even the patron wishes to not read any information or transmit any information). Device 1 contains arbiter 36 in the event that the closed switches 35 correspond to overlapping or conflicting information. Arbiter 36 will determine what information tag 34 can send or receive when a total personal profile includes conflicting options (i.e., in the event that both “limited” and “full” are capable of being selected simultaneously in the example of FIG. 1). Arbiter 36 is any arbiter known to one of skill in the art.

FIG. 4 depicts device 1 with memory 30 external to device 1. External device 40 contains memory 30 and may be accessed by device 1 either wirelessly (i.e., transceiver 42 communicates with transceiver 41) or through a wired connection. When a reader either transmits information to tag 34 or requests information from tag 34, transceiver 42 within device 1 communicates with transceiver 41 in a separate device 40 to read memory 30. Memory 30 contains what information may be transmitted or received according to a patrons selected options as determined by which switches 35 are closed and/or opened. External device 40 may be, for example, a mobile phone, PDA, or any other portable device capable of containing a memory.

FIG. 5 depicts device 1 capable of being separated into two segments 50 and 51 whereby segment 51 includes a USB connector 53 that can be input into a USB port of a microcomputer (not shown) to enable the storing information pertaining to at least one option in memory 30. Additionally, information can be wirelessly stored on memory 30 by either transmitting it to a transceiver contained in device 1, or to tag 34.

The information stored in memory 30 forms both options and settings which together form a subset, based upon which device 1 transmits or receives. FIG. 6 depicts three such settings 60, 61, 62. Payment setting 60 includes visa option 600 (e.g., visa account number), amex option 601 (e.g., amex account number), and debit option 602 (e.g., debit account number). Settings can contain any number of options a user desires. As an example, a patron may add Mastercard option 603 and designate a corresponding switch 35 or setting to enable selection of that option. Mode setting 61 contains new option 604 (i.e., products newly available within the last six months), offers option 605 (i.e., offers available in a given time range), and deal option 606 (i.e., discounts up to 50%). Additionally, a patron may add a coupons option 607 (i.e., what coupons are available for use with a given range of products). Access setting 62 contains none option 608 (i.e., no information may be transmitted), limited option 609 (i.e., limited information may be transmitted), and full option on 610 (i.e., all information will be transmitted). Additionally, a patron may generate a custom option 611 whereby only specific information customized by the patron will be transmitted.

Options may also contain additional levels of granularity. For example, FIG. 7 depicts a more detailed view of mode setting 61. New option 604 contains options 604a-604d corresponding to additional levels of detail. For example, a patron may wish to only receive information related to new products available within the last six months. This may be option 604a. Option 604b may be, for example, new products available within the last year. Option 604c may be, for example, new services available within the last six months. Option 604d may be, for example, new services available within the past year. A patron, depending on a desired level of granularity, can program any number of detailed options.

As additional examples, offers option 605 can include options 605a (i.e., offers available in the past week), 605b (i.e., offers available in the past month), 605c (i.e., ongoing offers), and 605d (i.e., future offers). Further, deal option 606 can include options 606a (i.e., minimum 10% discount), 606b (i.e., minimum 20% discount), 606c (i.e., minimum 50% discount), and 606d (i.e., all available discounts). A patron may also program a personal profile selection component to select more than one option (i.e., new options 604 equals 604a and 604b, offers option 605 includes option 605d, and deal option 606 includes 606a, and 606c). Additionally, any option can be set to receive or transmit all information available to device 1.

With regard to access setting 62, FIG. 8 depicts a matrix into which a patron can enter information they wish available for transmission. None option 608 may contain, for example, only basic information such as name, age, address, product preferences, etc. Limited option 609 may contain more detailed information including, for example, gender, race, ethnicity, sexual orientation, height, weight, hair color, eye color, occupation, hobbies, phone number, marital status, shoe size, clothing size, etc. Limited option 609 is depicted in FIG. 8 as containing information in both limited option 609 and none option 608, so selecting limited option 609 will allow transmission of both options. Full option 610 may contain, for example, driver's license number, social security number, government id number, education, salary, medical history, mobile number, etc. Full option 610 also may include all the information in limited option 609 and none option 608. Further, in the interests of protecting privacy, a patron may also customize the information they wish available for transmission in one or all of the options in access setting 62 depending upon their individual comfort level.

FIG. 9 depicts a system for allowing a personal profile to be read. In the system of FIG. 9, environment 90 includes a shop inventory database 91, a customer database 92, and a front-end interface 93 that includes, for example, a tag reader and a tag writer. A patron enters environment 90 with a personal profile subset selected on device 1. Front-end interface 93 transmits information entered by the proprietor and reads all information available to it from patrons. Device 1 will only allow the transmission of the personal profile subset and reception of a limited amount of information enabled by the personal profile selection components in device 1. In this manner, patrons will only receive the information they desire as well as allowing proprietors to know personal information the patron specifies.

FIG. 10 depicts a flow chart of a method of selecting a personal profile in an environment. In this method, a patron enters a personal profile into memory 30 in step 100. The user then generates at least one subset of the personal profile by selecting selection components 2, 3, 4 in step 101. Step 101 can also be automatically performed by a processor which recognizes the information entered by a patron and automatically sorts it into various options. Device 1 selects the subset and tag 34 transmits or receives information based on the subset when it receives a request from an environment to do so in step 102. Device 1 may also perform step 101a which is identifying a particular environment (i.e., a retail environment, a particular type of store, a restaurant, etc.). This may trigger additional steps of generating a subset based on the type of environment in step 101b, and selecting the generated subset in step 101c prior to the tag 34 transmitting or receiving information based on the subset when it receives a request from an environment to do so in step 102.

The present invention has been described with respect to particular illustrative embodiments. It is to be understood that the invention is not limited to the above-described embodiments and modifications thereto, and that those of ordinary skill in the art may make various changes and modifications without departing from the spirit and scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof;

f) hardware portions may be comprised of one or both of analog and digital portions;

g) any of the disclosed devices or portions thereof may be combined together or separated into further portions unless specifically stated otherwise; and

h) no specific sequence of acts is intended to be required unless specifically indicated.

What is claimed is:

1. A device 1 for transmitting a personal profile comprising:
a memory 30 containing a personal profile;
a personal profile selection component 2; and
a transmitter 34 for transmitting a signal, said signal comprising at least one subset of the personal profile selected using the personal profile selection component 2.

2. The device 1 of claim 1, wherein the personal profile further comprises more than one subset.

3. The device 1 of claim 1, wherein the personal profile selection component 2, 3, 4 comprises a switch 35.

4. The device 1 of claim 3, wherein the switch 35 is manually operable by a user.

5. The device 1 of claim 1, wherein the transmitter 34 further comprises an RFID.

6. The device 1 of claim 1, wherein the device 1 further comprises a transceiver 34 which receives a request to transmit the at least one subset of the personal profile from a reader.

7. The device 1 of claim 6, wherein the reader exclusively receives said signal.

8. The device 1 of claim 1, wherein the personal profile may be altered and stored in the memory 30.

9. The device 1 of claim 8, wherein the memory 30 is altered wirelessly, through a wired connection, or both.

10. The device 1 of claim 1, wherein the at least one personal profile comprises information regarding user status, transmitter mode, reader access, and/or payment.

11. The device 1 of claim 1, wherein the device 1 comprises a key chain, a credit card, a smart card, a mobile phone, a PDA, a wireless device, a portable microcomputer, or a wearable device.

12. A device 1 for limiting the transmission and/or receiving of a personal profile comprising:
a personal profile selection component 2, 3, 4 for selecting at least one subset of the personal profile; and
a transceiver 34 that transmits a signal upon receiving a demand from a reader, said signal comprising at least one subset of the personal profile selected using the personal profile selection component 2, 3, 4.

13. The device 1 of claim 12, wherein a user defines at least one setting and at least one option, said option and setting forming the at least one subset.

14. The device 1 of claim 12, wherein the memory 30 is programmable and the user can program at least one parameter of the at least one subset.

15. The device 1 of claim 12, wherein the transceiver 34 accesses a memory 30 that is external to the device 1 and can be accessed wirelessly by the device 1.

16. The device 1 of claim 12, wherein the transceiver 34 further comprises an RFID tag.

17. The device 1 of claim 12, wherein the transceiver 34 receives a signal containing information and only stores the information in the memory 30 if the information matches an option contained in the subset of the personal profile.

18. A device 1 for selecting and transmitting a personal profile comprising:
a memory 30 containing a personal profile having at least a first and a second subset;
at least two personal profile selection components 2, 3, 4 for selecting the first and/or the second subset of the personal profile; and
a transmitter 34 for transmitting the first and/or the second subset.

19. The device 1 of claim 18, wherein the device 1 further comprises an arbiter 35 for selecting an overlap between the first and the second subsets.

20. The device 1 of claim 19, wherein the arbiter 35 comprises software, hardware, or both software and hardware.

21. The device 1 of claim 19, wherein the transmitter 34 transmits a signal comprising the selected overlap.

22. A system for allowing a personal profile to be read comprising:
a device 1 comprising
a memory 30 containing a personal profile;
a personal profile selection component 2, 3, 4; and
a tag 34 for transmitting a signal;
a reader configured to transmit a request, wherein said tag transmits said signal, and wherein said signal comprises exclusively at least one subset of the personal profile selected using the personal profile selection component.

23. A method of selecting a personal profile in an environment comprising:
entering a personal profile in a memory;
generating at least one subset of the personal profile;
selecting the at least one subset;
transmitting and/or receiving information based on the at least one subset upon receiving a request in the environment.

24. The method of claim 23, wherein the generating step further comprises generating at least two subsets.

25. The method of claim 23, wherein the generating step further comprises automatically generating the at least one subset from the personal profile.

26. The method of claim 23, wherein the method further comprises receiving a request to transmit from a triggering the selection step by recognizing a request to transmit from an environment.

27. The method of claim 26, wherein the recognizing step further comprises identifying the source of the triggering step and transmitting the subset based the environment's identification.

28. The method of claim 23, wherein the method further comprises receiving a request to transmit from a reader in an environment.
